(19) United States
(12) Patent Application Publication
(10) Pub. No.: US 2026/0047349 A1
(43) Pub. Date: Feb. 12, 2026

(54) SUPERCONDUCTING QUANTUM CIRCUIT, QUANTUM DEVICE, AND METHOD FOR MANUFACTURING SUPERCONDUCTING QUANTUM CIRCUIT

(71) Applicant: NEC Corporation, Tokyo (JP)

(72) Inventor: Ayuka TADA, Tokyo (JP)

(73) Assignee: NEC Corporation, Tokyo (JP)

(21) Appl. No.: 19/277,860

(22) Filed: Jul. 23, 2025

(30) Foreign Application Priority Data
Aug. 7, 2024 (JP) 2024-130753

(51) Int. Cl. H10N 60/12; H10N 60/01; H10N 60/80

(52) U.S. Cl. CPC H10N 60/12; H10N 60/0912; H10N 60/805

(57) ABSTRACT

A superconducting quantum circuit includes a substrate, a pair of main patterns, a pair of first conductor patterns, a pair of second conductor patterns, and a Josephson junction portion, in which a boundary line between the substrate and the pair of main patterns in plan View includes an opposing boundary line located on a side on which the pair of main patterns face each other in a first direction and a non-opposing boundary line other than the opposing boundary line, the pair of first conductor patterns includes a ride-on portion that rides on the pair of main patterns from the substrate, and the ride-on portion is formed to overlap at least the non-opposing boundary line.

This application is based upon and claims the benefit of priority from Japanese patent application No. 2024-130753, filed on August 7, 2024, the disclosure of which is incorporated herein in its entirety by reference.

### TECHNICAL FIELD

The present disclosure relates to a superconducting quantum circuit, a quantum device, and a method for manufacturing a superconducting quantum circuit.

### BACKGROUND ART

It is known that a superconducting quantum circuit is used for a quantum device mounted on a quantum computer or the like.

For example, WO 2022/118464 A1 discloses a superconducting quantum circuit including a plurality of first conductors formed in layers with a superconducting material, a plurality of second conductors formed of a superconducting material in which at least one part is laminated on the first conductors, and a conductor layer formed of a superconducting material.

### SUMMARY

In the superconducting quantum circuit disclosed in WO 2022/118464 A1, a first conductor is formed on a conductor layer formed on a substrate by oblique deposition (first time) from a first direction by way of a resist mask. Thereafter, an oxide film is formed on the surface of the first conductor, and a second conductor is formed on the first conductor by oblique deposition (second time) from a second direction by way of the resist mask. As a result, the first conductor and the second conductor are joined to each other by Josephson junction by way of the oxide film.

Since the conductor layer has a predetermined thickness, a step difference is generated at a boundary portion between the substrate and the conductor layer. Depending on the size of the step difference, the first conductor may not be deposited well at the boundary portion of the conductor layer. Therefore, there is room for improvement in connection between the conductor layer and the first conductor.

An object of the present disclosure is to provide a superconducting quantum circuit, a quantum device, and a method for manufacturing a superconducting quantum circuit that solve the above problems.

In order to solve the above problem, this disclosure proposes the following means.

A superconducting quantum circuit according to the present disclosure includes: a substrate, and a laminated body of a superconducting material formed on the substrate, in which
the laminated body includes: a pair of main patterns formed spaced apart from each other in a first direction on the substrate, and a connection pattern formed on the substrate and the pair of main patterns to connect the pair of main patterns, the connection pattern includes: a pair of first conductor patterns extending in the first direction, having a first gap portion for spacing apart in the first direction, and having an oxide film formed on a surface, a pair of second conductor patterns extending in the first direction, having a second gap portion for spacing apart in the first direction, and overlapping the pair of first conductor patterns while being shifted in the first direction in such a way as to straddle the first gap portion, and a Josephson junction portion located between the first gap portion and the second gap portion in plan view and formed by overlapping one of the pair of first conductor patterns and one of the pair of second conductor patterns by way of the oxide film, a boundary line between the substrate and the pair of main patterns in plan view includes: an opposing boundary line located on a side where the pair of main patterns face each other in the first direction, and a non-opposing boundary line other than the opposing boundary line, the pair of first conductor patterns includes a ride-on portion riding on the pair of main patterns from the substrate, and the ride-on portion is formed in such a way as to overlap at least the non-opposing boundary line.

In addition, a quantum device according to the present disclosure includes the superconducting quantum circuit.

Furthermore, a method for manufacturing a superconducting quantum circuit according to the present disclosure includes: forming a laminated body of a superconducting material on a substrate, in which the step of forming the laminated body includes: forming a pair of main patterns spaced apart from each other in a first direction on the substrate, and forming a connection pattern on the substrate and the pair of main patterns to connect the pair of main patterns, the step of forming the connection pattern includes: forming a pair of first conductor patterns extending in the first direction and having a first gap portion for spacing apart in the first direction by a first oblique deposition from one side in the first direction via a mask having a pair of openings spaced apart from each other in the first direction, forming an oxide film on a surface of the pair of first conductor patterns, and forming a pair of second conductor patterns extending in the first direction and having a second gap portion for spacing apart in the first direction by a second oblique deposition from the other side in the first direction via the mask to overlap the pair of first conductor patterns while being shifted in the first direction in such a way as to straddle the first gap portion, and forming a Josephson junction portion located between the first gap portion and the second gap portion in plan view by overlapping one of the pair of first conductor patterns and one of the pair of second conductor patterns by way of the oxide film, a boundary line between the substrate and the pair of main patterns in plan view includes: an opposing boundary line located on a side where the pair of main patterns face each other in the first direction, and a non-opposing boundary line other than the opposing boundary line, and in the step of forming the pair of first conductor patterns, the pair of first conductor patterns forms a ride-on portion riding on the pair of main patterns from the substrate, and forms the ride-on portion in such a way as to overlap at least the non-opposing boundary line.

According to the present disclosure, the main pattern formed on the substrate and the first conductor pattern riding on the main pattern can be reliably connected.

### BRIEF DESCRIPTION OF THE DRAWINGS

Exemplary features and advantages of the present disclosure will become apparent from the following detailed description when taken with the accompanying drawings in which:

FIG. 1 is a plan view of a superconducting quantum circuit according to a minimum configuration example of the present disclosure;

FIG. 2 is a plan view of the superconducting quantum circuit according to a first example embodiment of the present disclosure;

FIG. 3 is a cross-sectional view taken along line III-III illustrated in FIG. 2;

FIG. 4 is an enlarged plan view of a region A illustrated in FIG. 3;

FIGS. 5A to SE are process charts illustrating a method for manufacturing the superconducting quantum circuit according to the first example embodiment of the present disclosure;

FIGS. 6A to 6D are process charts illustrating a method for manufacturing the superconducting quantum circuit according to the first example embodiment of the present disclosure;

FIGS. 7A to 7D are process charts illustrating a method for manufacturing the superconducting quantum circuit according to the first example embodiment of the present disclosure;

FIG. 8 is a plan View of a superconducting quantum circuit according to a second example embodiment of the present disclosure;

FIG. 9 is an enlarged plan View of the main part of the superconducting quantum circuit according to the second example embodiment of the present disclosure;

FIG. 10 is a plan View of a superconducting quantum circuit according to a third example embodiment of the present disclosure; and

FIG. 11 is an enlarged plan View of the main part of the superconducting quantum circuit according to the third example embodiment of the present disclosure.

### EXAMPLE EMBODIMENT

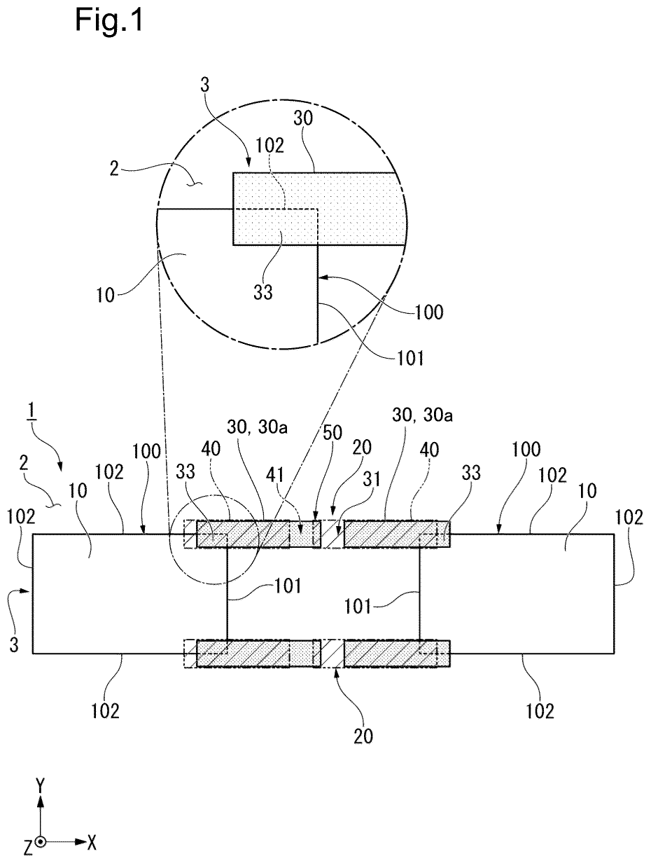

A minimum configuration example of the present disclosure will be described with reference to FIG. 1.

FIG. 1 is a plan View of a superconducting quantum circuit 1 according to a minimum configuration example of the present disclosure. In FIG. 1, a part of the superconducting quantum circuit is illustrated in an enlarged manner in addition to the entire superconducting quantum circuit 1. In addition, in the plan view, for the sake of explanation, a first conductor pattern 30 under a second conductor pattern 40 is visualized at a portion Where the first conductor pattern 30 and the second conductor pattern 40 overlap. The same applies to other plan views.

As illustrated in FIG. 1, a superconducting quantum circuit 1 includes a substrate 2 and a laminated body 3 of a superconducting material formed on the substrate 2.

The laminated body 3 includes a pair of main patterns 10 formed on the substrate 2 while being separated from each other, and a connection pattern 20 formed on the substrate 2 and the pair of main patterns 10 to connect the pair of main patterns 10. The connection pattern 20 forms, for example, a superconducting quantum interference circuit (superconducting quantum interference device: SQUID). The pair of main patterns 10 is, for example, a resonance circuit and is connected to the connection pattern 20.

In the following description, an XYZ orthogonal coordinate system is set, and the position relationship of each member may be described with reference to the XYZ orthogonal coordinate system. A first direction that is a direction along the surface of the substrate 2 and in which the pair of main patterns 10 faces each other with a space therebetween is defined as an X-axis direction. Furthermore, a second direction that is a direction along the surface of the substrate 2 and is orthogonal to the X-axis direction is defined as a Y-axis direction. A third direction perpendicular to the surface of the substrate 2 is defined as a Z-axis direction.

A side on which an arrow in the X-axis direction in the drawing is directed is defined as a +X side, and a side opposite thereto is defined as a −X side. In addition, a side on which an arrow in the Y-axis direction in the drawing is directed is defined as a +Y side, and a side opposite thereto is defined as a −Y side. In addition, a side on which an arrow in the Z-axis direction in the drawing is directed is defined as a +Z side, and a side opposite thereto is defined as a −Z side. For the sake of convenience of description, the +Z side is defined as an upper side, and the −Z side is defined as a lower side, but the Z-axis direction may not coincide with the gravity direction.

The connection pattern 20 includes a first conductor pattern 30, a second conductor pattern 40, and a Josephson junction portion 50. A pair of first conductor patterns 30 is formed on the substrate 2 and the pair of main patterns 10. The pair of first conductor patterns 30 extends in the X-axis direction and has a first gap portion 31 for spacing apart in the X-axis direction. An oxide film 30a is formed on the surfaces of the pair of first conductor patterns 30.

A pair of second conductor patterns 40 is formed on the substrate 2, the pair of main patterns 10, and the pair of first conductor patterns 30. The pair of second conductor patterns 40 extends in the X-axis direction and has a second gap portion 41 for spacing apart in the X-axis direction. The pair of second conductor patterns 40 is substantially the same pattern as the pair of first conductor patterns 30, but is overlapped on the pair of first conductor patterns 30 while being shifted in the X-axis direction in such a way as to straddle the first gap portion 31.

The Josephson junction portion 50 is located between the first gap portion 31 and the second gap portion 41 in plan view, and is formed by overlapping one of the pair of first conductor patterns 30 (the first conductor pattern 30 disposed on the −X side) and one of the pair of second conductor patterns 40 (the second conductor pattern 40 disposed on the +X side) Via the oxide film 30a.

A step difference corresponding to the thickness of the main pattern 10 is formed at a boundary line 100 between the substrate 2 and the pair of main patterns 10 in plan View. The pair of first conductor patterns 30 includes a ride-on portion 33 that rides on the pair of main patterns 10 from the substrate 2.

The boundary line 100 includes an opposing boundary line 101 located on a side where the pair of main patterns 10 face each other in the X-axis direction, and a non-opposing boundary line 102 other than the opposing boundary line 101. For example, when described with the boundary line 100 having a rectangular shape around the main pattern 10 located on the −X side, one side arranged on the +X side and extending in the Y-axis direction is the opposing boundary line 101, and the other three sides are the non-opposing boundary lines 102.

The ride-on portion 33 is formed in such a way as to overlap at least the non-opposing boundary line 102. As will be described later, for example, when first conductor pattern 30 is formed by oblique deposition from one side (−X side) toward the other side (+X side) in the X-axis direction, there is a possibility that a step difference of the main pattern 10 becomes a shadow at a portion of the opposing boundary line 101 of the main pattern 10 located on the −X side and the first conductor pattern 30 may not be formed well, whereas such a possibility is small at a portion of the non-opposing boundary line 102.

According to the superconducting quantum circuit 1 described above, since the ride-on portion 33 is formed in such a way as to overlap at least the non-opposing boundary line 102 and has the connection structure via the non-opposing boundary line 102, the main pattern 10 formed on the substrate 2 and the first conductor pattern 30 riding on the main pattern 10 can be reliably connected.

In addition, according to the quantum device including the superconducting quantum circuit 1, since the superconducting quantum circuit 1 functions normally, and thus a deviation in characteristics from a design can be suppressed.

Furthermore, in the superconducting quantum circuit 1 described above, the direction in which the current flows and the direction in which the first conductor pattern 30 and the second conductor pattern 40 are obliquely deposited coincide with each other in the X-axis direction in plan view. Therefore, according to the method for manufacturing the superconducting quantum circuit 1, the number of manufacturing processes can be reduced as compared with a manufacturing method in which the first conductor pattern 30 and the second conductor pattern 40 are obliquely deposited from a direction different from the X-axis direction, and furthermore, the size of the superconducting quantum circuit 1 in the Y-axis direction can be reduced.

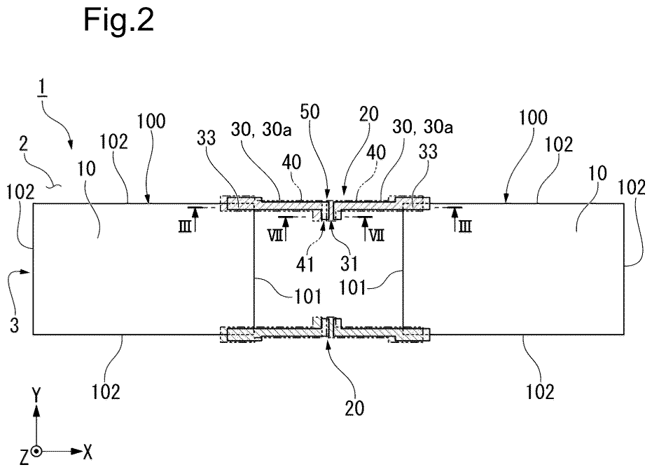

Next, a first example embodiment of the present disclosure will be described with reference to FIGS. 2, 3, 4, 5A to 5E, 6A to 6D, and 7A to 7D in addition to FIG. 1. In FIGS. 2, 3, 4, 5A to SE, 6A to 6D, and 7A to 7D, the same reference numerals are given to the same configurations as those in FIG. 1, and the description will be simplified.

### First Example Embodiment

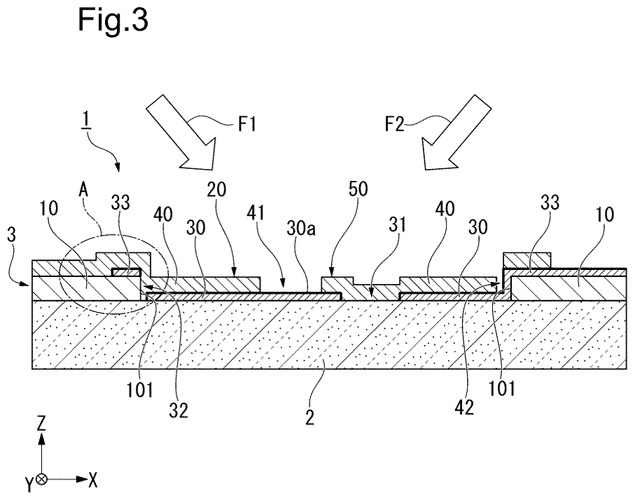

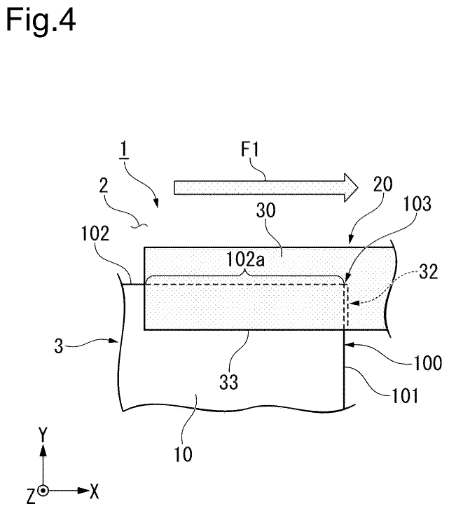

FIG. 2 is a plan view of the superconducting quantum circuit 1 according to a first example embodiment of the present disclosure. FIG. 3 is a cross-sectional view taken along line III-III illustrated in FIG. 2. FIG. 4 is an enlarged plan view of a region A illustrated in FIG. 3.

As illustrated in FIG. 2, the superconducting quantum circuit 1 includes a substrate 2 and a laminated body 3. The laminated body 3 includes a pair of main patterns 10 and a connection pattern 20.

The connection pattern 20 illustrated in FIG. 2 includes a pair of first conductor patterns 30 and a pair of second conductor patterns 40 formed in an L shape in plan view. As described above, the pair of first conductor patterns 30 and the pair of second conductor patterns 40 are each formed in an L shape in plan view, and portions bent in the L shape are overlapped, whereby the Josephson junction portion 50 can be stably formed.

Furthermore, as illustrated in FIG. 2, the connection pattern 20 is separated in the Y-axis direction, but may not be separated in the Y-axis direction. For example, both end portions of the connection pattern 20 in the X-axis direction may be connected with a pattern extending in the Y-axis direction to form a rectangular shape as a whole. However, in this case, the wiring area of the connection pattern 20 increases.

A place where the connection pattern 20 is film-formed is an etching portion as described later. For example, in a case where an oxide film on the surface of the substrate 2 and the surface of the main pattern 10 is removed by RF etching or the like before the first conductor pattern 30 is film-formed, an increase in surface roughness or a defect of a crystal structure occurs in these etching portions, that causes a loss factor of the superconducting quantum circuit 1.

Therefore, as illustrated in FIG. 2, the loss factor of the superconducting quantum circuit 1 can be reduced by separating the connection pattern 20 in the Y-axis direction and reducing the wiring area of the connection pattern 20.

On the other hand, when the wiring area of the connection pattern 20 is reduced, the tunnel current between the main pattern 10 and the connection pattern 20 becomes small, and hence unless the main pattern 10 and the connection pattern 20 are reliably connected, an unintended portion behaves as a Josephson junction portion, that causes the characteristic of the superconducting quantum circuit 1 to deviate from the design.

The substrate 2 is formed of, for example, a material such as silicon, sapphire, or a compound semiconductor. Furthermore, the substrate 2 may be formed of single crystal, polycrystal, amorphous, or the like. Moreover, the substrate 2 may be a high-resistance semiconductor substrate.

As illustrated in FIG. 3, the main pattern 10, the first conductor pattern 30, and the second conductor pattern 40 are laminated on the substrate 2. The main pattern 10 is formed in a first layer of the laminated body 3. The first conductor pattern 30 is formed in a second layer of the laminated body 3. The second conductor pattern 40 is formed in a third layer of the laminated body 3.

The main pattern 10 is made of a superconducting material such as niobium (Nb). A material for forming the main pattern 10 is not limited to niobium (Nb). The main pattern 10 forms a circuit such as, for example, wiring, a resonator, a capacitor, and a ground plane.

The first conductor pattern 30 and the second conductor pattern 40 form a superconducting quantum interference circuit Via the Josephson junction portion 50. The first conductor pattern 30 and the second conductor pattern 40 are made of a superconducting material such as aluminum (Al). The material for forming the first conductor pattern 30 and the second conductor pattern 40 is not limited to aluminum (Al).

The first conductor pattern 30 is laminated on the substrate 2 and the main pattern 10. Furthermore, the second conductor pattern 40 is laminated on the substrate 2, the main pattern 10, and the first conductor pattern 30. An oxide film 30a (AlOx: aluminum oxide) is formed between the first conductor pattern 30 and the second conductor pattern 40. The oxide film 30a functions as a tunnel barrier layer of the Josephson junction portion 50.

The oxide film 30a is formed on a surface of first conductor pattern 30 that is not in contact with the substrate 2 and the main pattern 10. The oxide film 30a is formed by, for example, performing oxidation process on the surface of the first conductor pattern 30 before laminating the second conductor pattern 40 on the first conductor pattern 30.

The Josephson junction portion 50 is formed at a central portion in the longitudinal direction (X-axis direction) of the connection pattern 20. The Josephson junction portion 50 is formed by one of the pair of first conductor patterns 30 (the first conductor pattern 30 arranged on the −X side) and one of the pair of second conductor patterns 40 (the second conductor pattern 40 arranged on the +X side) overlapping each other by way of the oxide film 30a.

As will be described later, the Josephson junction portion 50 is formed by an oblique deposition method. In this method, a mask corresponding to the shapes of the first conductor pattern 30 and the second conductor pattern 40 is provided in advance on the substrate 2. Then, the deposition direction with respect to the substrate 2 is changed, and thin films (the first conductor pattern 30 and the second conductor pattern 40) of the superconducting material are film-formed twice.

In the first deposition treatment, as indicated by an arrow F1 in FIG. 3, the pair of first conductor patterns 30 is formed by performing oblique deposition from the −X side to the +X side in the X-axis direction while being inclined to the −X side by a predetermined angle with respect to the direction perpendicular to the surface of the substrate 2. In the second deposition treatment, as indicated by an arrow F2 in FIG. 2, the pair of second conductor patterns 40 is formed by performing oblique deposition from the +X side to the −X side in the X-axis direction while being inclined to the +X side by a predetermined angle with respect to the direction perpendicular to the surface of the substrate 2.

In the first deposition treatment, since oblique deposition is performed as indicated by arrow F1, there is a possibility that the step difference of the main pattern 10 becomes a shadow and a step-cut portion 32 of the first conductor pattern 30 is generated at the portion of the opposing boundary line 101 of the main pattern 10 located on the −X side. On the other hand, at the portion of the opposing boundary line 101 of the main pattern 10 located on the +X side, the first conductor pattern 30 is film-formed toward the step difference of the main pattern 10, and thus the possibility of the step-cut portion 32 being generated is small. In the second deposition treatment, since the oblique deposition is performed in a direction opposite to the first deposition treatment in the X-axis direction, there is a possibility that a step-cut portion 42 is generated on the +X side.

As illustrated in FIG. 4, the first conductor pattern 30 includes a ride-on portion 33 that rides on the main pattern 10 from the substrate 2. The ride-on portion 33 is formed in such a way as to overlap at least the non-opposing boundary line 102. Specifically, the non-opposing boundary line 102 overlapped by the ride-on portion 33 includes a parallel portion 102a extending in parallel with the X-axis direction in plan view. Since the parallel portion 102a is parallel to the X-axis direction in which oblique deposition is performed in plan view, it is less likely to become a shadow of the main pattern 10, and the possibility of the step-cut portion 32 of the first conductor pattern 30 being generated is small.

As described above, even if the step-cut portion 32 of the first conductor pattern 30 is generated at the opposing boundary line 101 by oblique deposition indicated by reference sign F1, the main pattern 10 formed on the substrate 2 and the first conductor pattern 30 riding on the main pattern 10 can be reliably connected by providing the connection structure via the non-opposing boundary line 102. As a result, the superconducting quantum circuit 1 functions normally, and hence the deviation of the characteristic from the design can be suppressed.

Furthermore, the ride-on portion 33 is formed in such a way as to overlap a corner portion 103 where the opposing boundary line 101 and the non-opposing boundary line 102 intersect. As described above, by film-forming the first conductor pattern 30 in such a way as to overlap the corner portion 103 of the main pattern 10, the first conductor pattern 30 does not run out from the main pattern 10 as much, whereby the size of the superconducting quantum circuit 1 in the Y-axis direction can be reduced while providing the connection structure via the non-opposing boundary line 102.

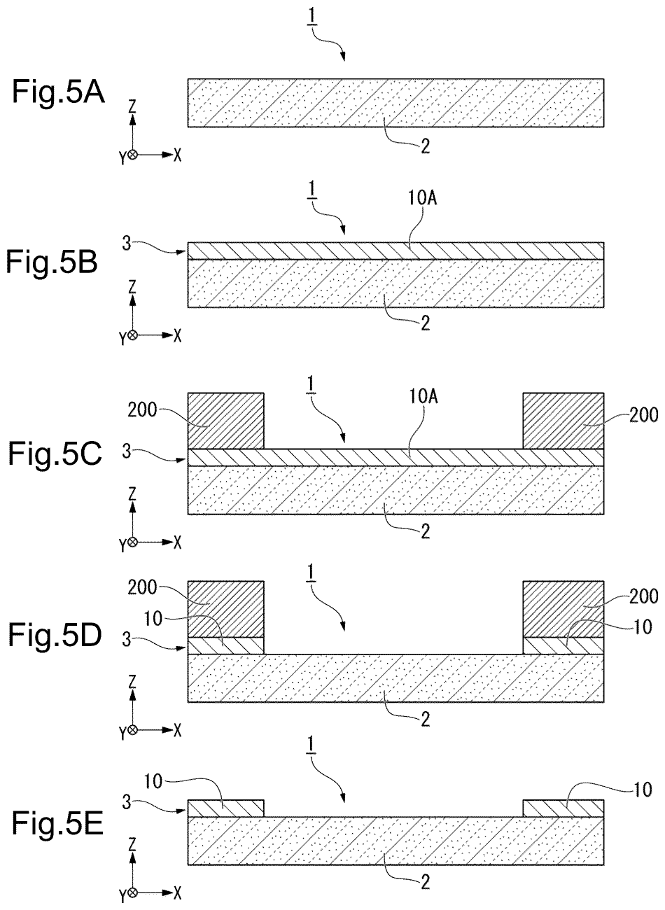

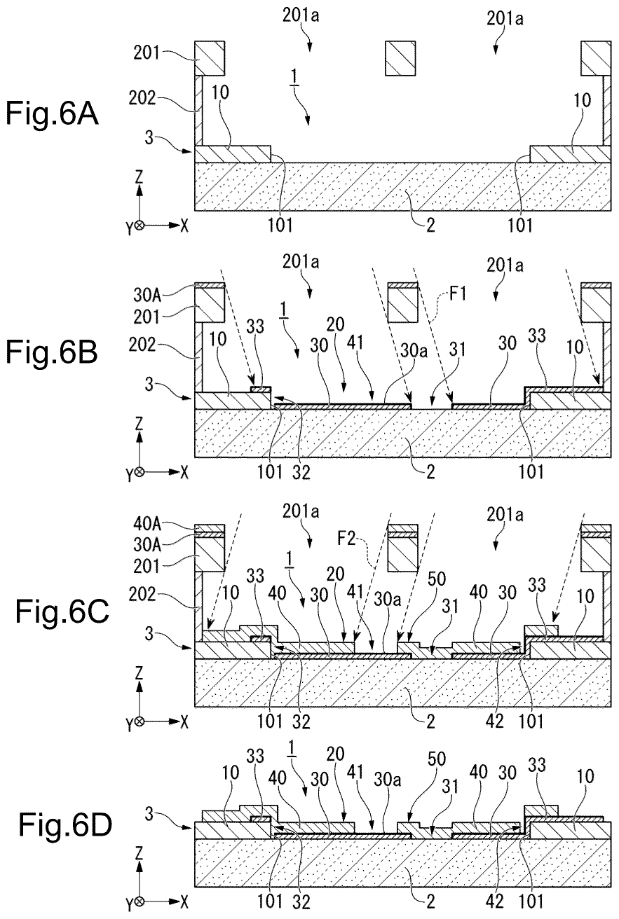

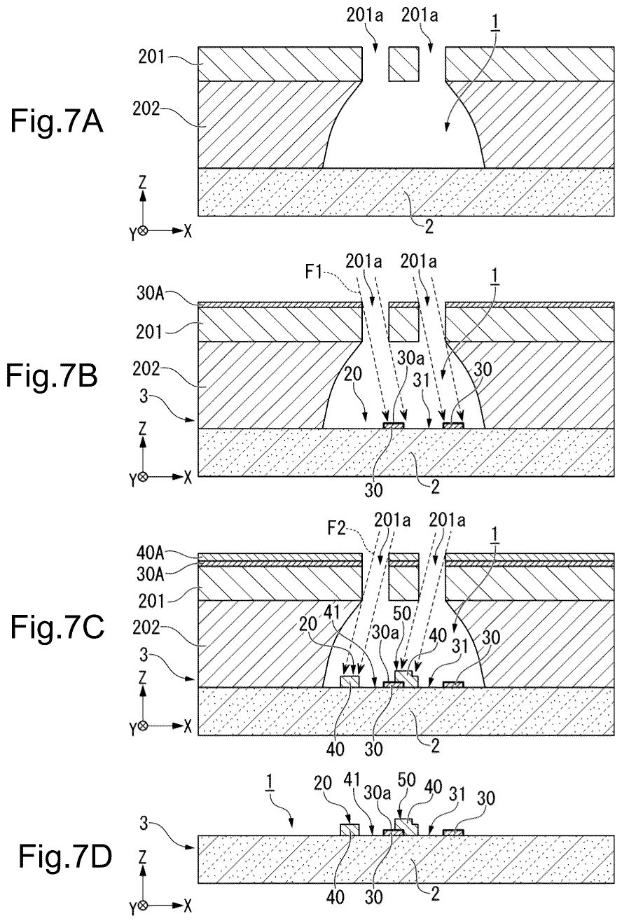

FIGS. 5A to SE, 6A to 6D, and 7A to 7D are process charts illustrating a method for manufacturing the superconducting quantum circuit 1 according to the first example embodiment of the present disclosure. Similarly to FIG. 3, FIGS. 6A to 6D correspond to the cross section taken along line III-III illustrated in FIG. 2. FIGS. 7A to 7D correspond to the cross section taken along line VII-VII illustrated in FIG. 2.

First, as illustrated in FIG. 5A, the substrate 2 is prepared. Next, as illustrated in FIG. 5E, a first conductor layer 10A (Nb layer) is film-formed on the surface of the substrate 2.

The main pattern 10 is formed by, for example, a combination of optical lithography and reactive ion etching. First, as illustrated in FIG. 5C, a pattern corresponding to the main pattern 10 is formed on a resist 200 film-formed on the first conductor layer 10A by optical lithography. Next, as illustrated in FIG. 5D, the main pattern 10 is formed by reactive ion etching. Thereafter, as illustrated in FIG. 5E, the resist 200 that is no longer necessary is removed.

The film-formation of the main pattern 10 may be performed by, for example, sputtering, vapor deposition, chemical vapor deposition (CVD), or the like. An electron beam drawing method or the like may be used instead of the optical lithography. In addition, wet etching or the like may be used instead of the reactive ion etching.

Next, as illustrated in FIG. 6A, a mask 201 and a mask 202 (resist mask) are formed on the substrate 2. Furthermore, until the mask 201 is removed, the mask 201 is not moved with respect to the substrate 2 and is fixed at a predetermined height by the mask 202.

In the mask 201, for example, a pair of openings 201a corresponding to the first conductor pattern 30 and the second conductor pattern 40 is formed by electron beam drawing. The pair of openings 201a is formed to be spaced apart from each other in the X-axis direction. As a result, in the mask 201, a bridge portion that forms the first gap portion 31 and the second gap portion 41 is formed between the pair of openings 201a.

Next, as illustrated in FIG. 6B, the first conductor pattern 30 is film-formed by oblique deposition of the superconducting material 30A (Al layer) from the direction indicated by the arrow F1. The direction of the first oblique deposition is a direction inclined at, for example, about 20 degrees to the −X side with respect to the direction perpendicular to the surface of the substrate 2. The direction of oblique deposition is adjusted, for example, by tilting the substrate 2.

In this manner, the first conductor pattern 30 is formed by oblique deposition through the pair of openings 201a of the mask 201. At this time, the first conductor pattern 30 is shielded by the bridge portion between the pair of openings 201a, whereby the first gap portion 31 in which the first conductor pattern 30 is not film-formed on the substrate 2 is formed. After the first conductor pattern 30 is film-formed, the surface of the first conductor pattern 30 is oxidized.

Specifically, the surface of the first conductor pattern 30 is oxidized by introducing oxygen gas into a container in which the substrate 2 is disposed. As a result, an oxide film 30a (aluminum oxide) is formed on the surface of the first conductor pattern 30.

Next, as illustrated in FIG. 6C, the second conductor pattern 40 is film-formed by oblique deposition of the superconducting material 40A (Al layer) from the direction indicated by the arrow F2. The direction of the second oblique deposition is a direction inclined at, for example, about 20 degrees to the +X side with respect to the direction perpendicular to the surface of the substrate 2. The direction of oblique deposition may be adjusted, for example, by tilting the substrate 2 or by changing the direction of the nozzle injecting the superconducting material 40A.

In this manner, the second conductor pattern 40 is formed by oblique deposition through the pair of openings 201a of the mask 201. At this time, the second conductor pattern 40 is shielded by the bridge portion between the pair of openings 201a, whereby the second gap portion 41 in which the second conductor pattern 40 is not film-formed on the substrate 2 and the first conductor pattern 30 is formed.

At a portion located between the first gap portion 31 and the second gap portion 41 (immediately below the bridge portion between the pair of openings 201a) in plan view, the Josephson junction portion 50 in which one of the pair of first conductor patterns 30 and one of the pair of second conductor patterns 40 overlap is formed via the oxide film 30a. The direction of oblique deposition (the angle with respect to the direction perpendicular to the surface of the substrate 2) is determined by the first gap portion 31 and the second gap portion 41 such that the area of the Josephson junction portion 50 becomes appropriate.

Lastly, as illustrated in FIG. 6D, the mask 201 and the mask 202 are removed. As a result, the extra superconductive materials 30A and 40A laminated on the mask 201 are removed. In this way, the superconducting quantum circuit 1 illustrated in FIGS. 2 to 4 is manufactured. At the distal end portions of the pair of first conductor patterns 30 and the pair of second conductor patterns 40 formed in an L shape in plan view, the step proceeds as illustrated in FIGS. 7A to 7D.

The steps illustrated in FIGS. 7A to 7D correspond to the steps illustrated in FIGS. 6A to 6D described above, and will be simplified due to redundant description, but first, a mask 201 is formed as illustrated in FIG. 7A. Next, as illustrated in FIG. 7B, the first conductor pattern 30 is formed by oblique deposition from the direction indicated by the arrow F1. Next, as illustrated in FIG. 7C, the second conductor pattern 40 is formed by oblique deposition from the arrow F2. Lastly, as illustrated in FIG. 7D, the mask 201 and the mask 202 are removed.

As described above, the manufactured superconducting quantum circuit 1 includes the substrate 2 and the laminated body 3 of the superconducting material formed on the substrate 2 as illustrated in FIGS. 2 and 3. The laminated body 3 includes, on the substrate 2, the pair of main patterns 10 formed spaced apart from each other in the X-axis direction (first direction), and the connection pattern 20 formed on the substrate 2 and the pair of main patterns 10 to connect the pair of main patterns 10.

The connection pattern 20 includes a pair of first conductor patterns 30 extending in the X-axis direction, having the first gap portion 31 for spacing apart in the X-axis direction, and having the oxide film 30a formed on a surface thereof; a pair of second conductor patterns 40 extending in the X-axis direction, having the second gap portion 41 for spacing apart in the X-axis direction, and overlapping the pair of first conductor patterns 30 while being shifted in the X-axis direction to straddle the first gap portion 31; and the Josephson junction portion 50 located between the first gap portion 31 and the second gap portion 41 in plan view, and being formed by overlapping one of the pair of first conductor patterns 30 and one of the pair of second conductor patterns 40 via the oxide film 30a.

As illustrated in FIG. 2, a boundary line 100 between substrate 2 and the pair of main patterns 10 in plan view includes the opposing boundary line 101 located on a side where the pair of main patterns 10 face each other in the X-axis direction, and the non-opposing boundary line 102 other than the opposing boundary line 101. The pair of first conductor patterns 30 includes the ride-on portion 33 that rides on the pair of main patterns 10 from the substrate 2. As illustrated in FIG. 4, the ride-on portion 33 is formed in such a way as to overlap at least the non-opposing boundary line 102. According to this configuration, since the connection structure via the non-opposing boundary line 102 is provided, the main pattern 10 formed on the substrate 2 and the first conductor pattern 30 riding on the main pattern 10 can be reliably connected.

Furthermore, in the first example embodiment, the non-opposing boundary line 102 overlapped by the ride-on portion 33 includes a parallel portion 102a extending in parallel with the X-axis direction in plan view. According to this configuration, since parallel portion 102a is parallel to the X-axis direction in which oblique deposition is performed in plan view, it is less likely to become a shadow of the main pattern 10, and the possibility of the step-cut portion 32 of the first conductor pattern 30 generating at the non-opposing boundary line 102 is reduced.

In addition, in the first example embodiment, the ride-on portion 33 is formed in such a way as to overlap the corner portion 103 where the opposing boundary line 101 and the non-opposing boundary line 102 intersect. According to this configuration, since the first conductor pattern 30 does not run out from the main pattern 10 as much, the size of the superconducting quantum circuit 1 in the Y-axis direction can be reduced while including the connection structure via the non-opposing boundary line 102.

Moreover, in the first example embodiment, the pair of main patterns 10 is formed of a niobium material. The pair of first conductor patterns 30 is formed of an aluminum material. According to this configuration, the Nb layer and the Al layer in the superconducting quantum circuit 1 can be reliably connected.

In addition, according to the quantum device including the superconducting quantum circuit 1 of the first example embodiment, the superconducting quantum circuit 1 functions normally, and thus a deviation in characteristics from the design can be suppressed.

As illustrated in FIGS. 5A to SE, 6A to 6D, and 7A to 7D, the method for manufacturing the superconducting quantum circuit 1 according to the first example embodiment includes a laminated body forming step of forming the laminated body 3 of the superconducting material on the substrate 2. The laminated body forming step includes a main pattern forming step (see FIGS. 5A to 5E) of forming the pair of main patterns 10 spaced apart from each other in the X-axis direction on the substrate 2, and a connection pattern forming step (see FIGS. 6 and 7A to 7D) of forming the connection pattern 20 for connecting the pair of main patterns 10 on the substrate 2 and the pair of main patterns 10.

The connection pattern forming step includes: a first conductor pattern forming step (see FIG. 6B) of forming a pair of first conductor patterns 201 extending in the X-axis direction and having a first gap portion 31 for spacing apart in the X-axis direction by a first oblique vapor deposition from one side in the X-axis direction Via a mask 201 having a pair of openings 201a spaced apart in the X-axis direction; an oxide film forming step (see FIG. 6B) of forming an oxide film 30a on the surfaces of the pair of first conductor patterns 30; and a second conductor pattern forming step (see FIG. 6C of forming a pair of second conductor patterns 40 extending in the X-axis direction and having a second gap portion 41 for spacing apart in the X-axis direction by a second oblique deposition from the other side in the X-axis direction Via the mask 201 in such a way as to overlap the pair of first conductor patterns 30 while being shifted in the X-axis direction to straddle the first gap portion 31, and forming a Josephson junction portion 50 between the first gap portion 31 and the second gap portion 41 in plan view in which one of the pair of first conductor patterns 30 and one of the pair of second conductor patterns 40 overlap each other via the oxide film 30a.

A boundary line between the substrate 2 and the pair of main patterns 10 in plan view includes an opposing boundary line located on a side on which the pair of main patterns 10 face each other in the X-axis direction, and a non-opposing boundary line 102 other than the opposing boundary line, where in the first conductor pattern forming step, a ride-on portion 33 where the pair of first conductor patterns 30 rides on the pair of main patterns 10 from the substrate 2 is formed, and the ride-on portion 33 is formed in such a way as to overlap at least the non-opposing boundary line 102 (see FIG. 4).

According to this configuration, in plan view, a direction in which a current flows to the connection pattern 20 and a direction in which oblique deposition is performed on the first conductor pattern 30 and the second conductor pattern 40 coincide with each other in the X-axis direction. Therefore, according to the method for manufacturing the superconducting quantum circuit 1, the first conductor pattern 30 and the second conductor pattern 40 can be formed with the same mask 201, the number of manufacturing processes can be reduced as compared with a manufacturing method in which oblique deposition is performed on the first conductor pattern 30 and the second conductor pattern 40 from a direction different from the X-axis direction, and the size of the superconducting quantum circuit 1 in the Y-axis direction can be reduced.

### Second Example Embodiment

Next, a second example embodiment of the present disclosure will be described. In the following description, the same or equivalent components as those of the above-described example embodiment are denoted by the same reference numerals, and the description thereof will be simplified or omitted.

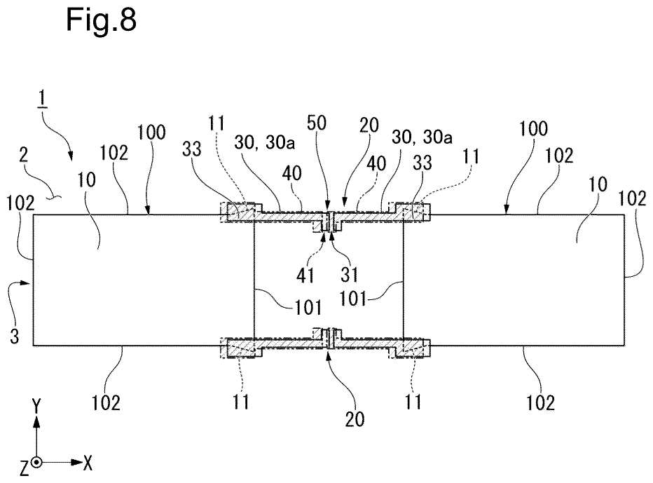

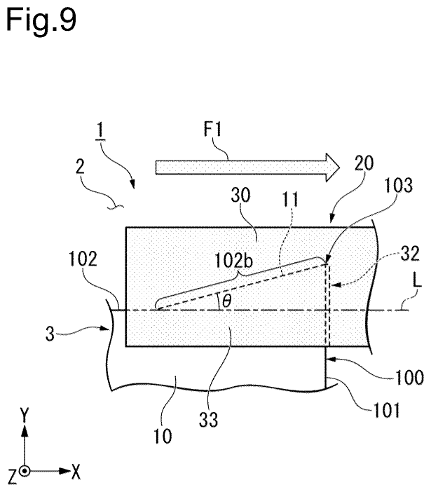

FIG. 8 is a plan view of the superconducting quantum circuit 1 according to the second example embodiment of the present disclosure. FIG. 9 is an enlarged plan View of the main part of the superconducting quantum circuit 1 according to the second example embodiment of the present disclosure.

As illustrated in these drawings, the main pattern 10 of the second example embodiment includes an extending portion 11 extending in a direction other than the X-axis direction in plan View. Furthermore, the ride-on portion 33 of the first conductor pattern 30 of the second example embodiment is formed in such a way as to overlap the extending portion 11.

Specifically, the extending portion 11 is formed at the corner portions 103 on both sides in the Y-axis direction on the side facing each other (on the opposing boundary line 101 side) of the pair of main patterns 10. As illustrated in FIG. 9, the extending portion 11 has a right triangular shape including an inclined portion 102b extending in a direction intersecting the X-axis direction. The inclined portion 102b is a part of the non-opposing boundary line 102, and is inclined at an angle θ in plan view with respect to the reference line L extending in the X-axis direction.

The angle θ is set in a range of equal to or greater than 0° and equal to or smaller than 179°. Preferably, the angle θ may be set in a range of equal to or greater than 0° and equal to or smaller than 90°. More preferably, the angle θ may be set in a range of equal to or greater than 0° and equal to or smaller than 45°. More preferably, the angle θ may be set in a range greater than 0° and smaller than 45°.

As described above, in the second example embodiment, the non-opposing boundary line 102 overlapped by the ride-on portion 33 includes the inclined portion 102b extending in the direction intersecting the X-axis direction in plan view. Since the step difference surface in the inclined portion 102b is formed in a direction having the X component facing the direction indicated by the arrow F1 in plan view in which the first conductor pattern 30 is obliquely deposited, the first conductor pattern 30 is reliably film-formed on the step difference surface. As a result, the main pattern 10 and the first conductor pattern 30 can be reliably connected to each other. In addition, when the angle θ is larger than 0° as compared with the case of 0°, the film-formation of the step difference surface in the inclined portion 102b becomes more reliable.

Furthermore, in the second example embodiment, the pair of main patterns 10 includes the extending portion 11 extending in a direction other than the X-axis direction in plan view, and at least a part of the non-opposing boundary line 102 overlapped by the ride-on portion 33 is formed in the extending portion 11. According to this configuration, the inclined portion 102b that reliably connects the main pattern 10 and the first conductor pattern 30 can be easily formed. Furthermore, when the angle θ is equal to or smaller than 45° or smaller than 45°, the extending portion 11 can have a small size. In particular, the inclined portion 102b can be in the form of the long extending portion 11 while maintaining the size in the Y-axis direction small. As a result, the step difference surface on which the first conductor pattern 30 is reliably film-formed can be made long in the inclined portion 102b, and the conductivity can be enhanced.

### Third Example Embodiment

Next, a third example embodiment of the present disclosure will be described. In the following description, the same or equivalent components as those of the above-described example embodiment are denoted by the same reference numerals, and the description thereof will be simplified or omitted.

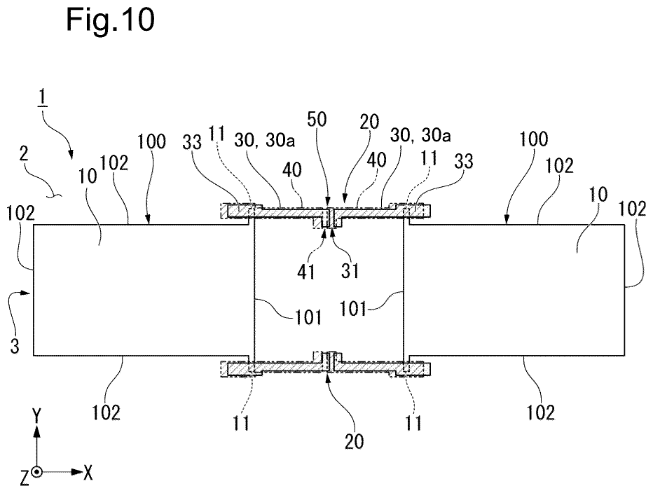

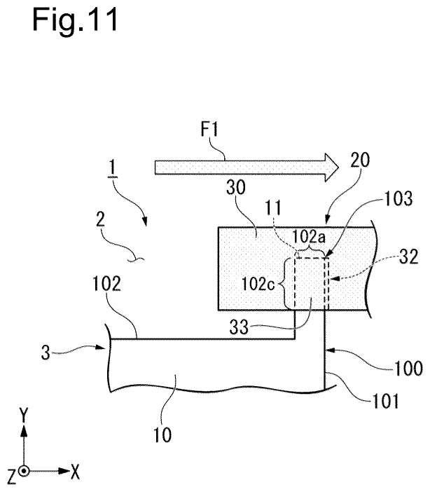

FIG. 10 is a plan view of the superconducting quantum circuit 1 according to the third example embodiment of the present disclosure. FIG. 11 is an enlarged plan view of the main part of the superconducting quantum circuit 1 according to the third example embodiment of the present disclosure.

As illustrated in these drawings, the non-opposing boundary line 102 overlapped by the ride-on portion 33 of the third example embodiment includes an orthogonal portion 102c extending in a direction (Y-axis direction) orthogonal to the X-axis direction in plan view.

Specifically, as illustrated in FIG. 11, the orthogonal portion 102c is formed in the extending portion 11 of the main pattern 10. The extending portion 11 of the third example embodiment has a rectangular shape extending in the Y-axis direction in plan view. The extending portion 11 includes the orthogonal portion 102c and the parallel portion 102a.

As described above, in the third example embodiment, the non-opposing boundary line 102 overlapped by the ride-on portion 33 includes the orthogonal portion 102c extending in the direction orthogonal to the X-axis direction in plan view. According to this configuration, since the step difference surface in the orthogonal portion 102c is formed in a direction facing the direction indicated by the arrow F1 in plan view in which the first conductor pattern 30 is obliquely deposited, the first conductor pattern 30 is reliably film-formed on the step difference surface. As a result, the main pattern 10 and the first conductor pattern 30 can be reliably connected to each other.

Although the example embodiments of the present disclosure have been described in detail with reference to the drawings, the specific configuration is not limited to these example embodiments, and includes design changes and the like within a range not departing from the gist of the present disclosure.

Each example embodiment can be appropriately combined with other example embodiments.

Furthermore, some or all of the above example embodiments may be described as the following supplementary notes, but are not limited to the following.

### Supplementary Note 1

A superconducting quantum circuit including:
a substrate, and
a laminated body of a superconducting material formed on the substrate, in which
the laminated body includes:
a pair of main patterns formed spaced apart from each other in a first direction on the substrate, and
a connection pattern formed on the substrate and the pair of main patterns to connect the pair of main patterns,
the connection pattern includes:
a pair of first conductor patterns extending in the first direction, having a first gap portion for spacing apart in the first direction, and having an oxide film formed on a surface,
a pair of second conductor patterns extending in the first direction, having a second gap portion for spacing apart in the first direction, and overlapping the pair of first conductor patterns while being shifted in the first direction in such a way as to straddle the first gap portion, and
a Josephson junction portion located between the first gap portion and the second gap portion in plan view and formed by overlapping one of the pair of first conductor patterns and one of the pair of second conductor patterns by way of the oxide film,
a boundary line between the substrate and the pair of main patterns in plan view includes:
an opposing boundary line located on a side where the pair of main patterns face each other in the first direction, and
a non-opposing boundary line other than the opposing boundary line,
the pair of first conductor patterns includes a ride-on portion riding on the pair of main patterns from the substrate, and
the ride-on portion is formed in such a way as to overlap at least the non-opposing boundary line.

### Supplementary Note 2

The superconducting quantum circuit according to supplementary note 1, in which
the non-opposing boundary line overlapped by the ride-on portion includes a parallel portion extending in parallel with the first direction in plan view.

### Supplementary Note 3

The superconducting quantum circuit according to supplementary note 1 or 2, in which
the non-opposing boundary line overlapped by the ride-on portion includes an inclined portion extending in a direction intersecting the first direction in plan view.

### Supplementary Note 4

The superconducting quantum circuit according to any one of supplementary notes 1 to 3, in which
the non-opposing boundary line overlapped by the ride-on portion includes an orthogonal portion extending in a direction orthogonal to the first direction in plan view.

### Supplementary Note 5

The superconducting quantum circuit according to any one of supplementary notes 1 to 4, in which
the pair of main patterns includes an extending portion extending in a direction other than the first direction in plan View, and
at least a part of the non-opposing boundary line overlapped by the ride-on portion is formed in the extending portion.

### Supplementary Note 6

The superconducting quantum circuit according to any one of supplementary notes 1 to 5, in which
the ride-on portion is formed to overlap a corner portion where the opposing boundary line and the non-opposing boundary line intersect.

### Supplementary Note 7

The superconducting quantum circuit according to any one of supplementary notes 1 to 6, in which
the pair of main patterns is formed of a niobium material.

### Supplementary Note 8

The superconducting quantum circuit according to any one of supplementary notes 1 to 7, in which
the pair of first conductor patterns is formed of an aluminum material.

### Supplementary Note 9

A quantum device equipped with the superconducting quantum circuit according to any one of supplementary notes 1 to 8.

### Supplementary Note 10

A method for manufacturing a superconducting quantum circuit including:
forming a laminated body of a superconducting material on a substrate, in which
the step of forming the laminated body includes:
forming a pair of main patterns spaced apart from each other in a first direction on the substrate, and
forming a connection pattern on the substrate and the pair of main patterns to connect the pair of main patterns,
the step of forming the connection pattern includes:
forming a pair of first conductor patterns extending in the first direction and having a first gap portion for spacing apart in the first direction by a first oblique deposition from one side in the first direction via a mask having a pair of openings spaced apart from each other in the first direction,
forming an oxide film on a surface of the pair of first conductor patterns, and
forming a pair of second conductor patterns extending in the first direction and having a second gap portion for spacing apart in the first direction by a second oblique deposition from the other side in the first direction via the mask to overlap the pair of first conductor patterns while being shifted in the first direction in such a way as to straddle the first gap portion, and forming a Josephson junction portion located between the first gap portion and the second gap portion in plan view by overlapping one of the pair of first conductor patterns and one of the pair of second conductor patterns by way of the oxide film,
a boundary line between the substrate and the pair of main patterns in plan view includes:
an opposing boundary line located on a side where the pair of main patterns face each other in the first direction, and
a non-opposing boundary line other than the opposing boundary line, and
in the step of forming the pair of first conductor patterns, the pair of first conductor patterns forms a ride-on portion riding on the pair of main patterns from the substrate, and forms the ride-on portion in such a way as to overlap at least the non-opposing boundary line.

1. A superconducting quantum circuit comprising:
a substrate; and
a laminated body of a superconducting material formed on the substrate; wherein
the laminated body includes:
a pair of main patterns formed spaced apart from each other in a first direction on the substrate, and
a connection pattern formed on the substrate and the pair of main patterns to connect the pair of main patterns;
the connection pattern includes:
a pair of first conductor patterns extending in the first direction, having a first gap portion for spacing apart in the first direction, and having an oxide film formed on a surface,
a pair of second conductor patterns extending in the first direction, having a second gap portion for spacing apart in the first direction, and overlapping the pair of first conductor patterns while being shifted in the first direction in such a way as to straddle the first gap portion, and
a Josephson junction portion located between the first gap portion and the second gap portion in plan View and formed by overlapping one of the pair of first conductor patterns and one of the pair of second conductor patterns by way of the oxide film;
a boundary line between the substrate and the pair of main patterns in plan View includes:
an opposing boundary line located on a side where the pair of main patterns face each other in the first direction, and
a non-opposing boundary line other than the opposing boundary line,
the pair of first conductor patterns includes a ride-on portion riding on the pair of main patterns from the substrate; and
the ride-on portion is formed in such a way as to overlap at least the non-opposing boundary line.

2. The superconducting quantum circuit according to claim 1, wherein the non-opposing boundary line overlapped by the ride-on portion includes a parallel portion extending in parallel with the first direction in plan view.

3. The superconducting quantum circuit according to claim 1, wherein
the non-opposing boundary line overlapped by the ride-on portion includes an inclined portion extending in a direction intersecting the first direction in plan view.

4. The superconducting quantum circuit according to claim 1, wherein
the non-opposing boundary line overlapped by the ride-on portion includes an orthogonal portion extending in a direction orthogonal to the first direction in plan view.

5. The superconducting quantum circuit according to claim 1, wherein
the pair of main patterns includes an extending portion extending in a direction other than the first direction in plan view, and
at least a part of the non-opposing boundary line overlapped by the ride-on portion is formed in the extending portion.

6. The superconducting quantum circuit according to claim 1, wherein
the ride-on portion is formed to overlap a corner portion where the opposing boundary line and the non-opposing boundary line intersect.

7. The superconducting quantum circuit according to claim 1, wherein
the pair of main patterns is formed of a niobium material.

8. The superconducting quantum circuit according to claim 1, wherein
the pair of first conductor patterns is formed of an aluminum material.

9. A quantum device comprising the superconducting quantum circuit includes:
a substrate; and
a laminated body of a superconducting material formed on the substrate; wherein
the laminated body includes:
a pair of main patterns formed spaced apart from each other in a first direction on the substrate, and
a connection pattern formed on the substrate and the pair of main patterns to connect the pair of main patterns;
the connection pattern includes:
a pair of first conductor patterns extending in the first direction, having a first gap portion for spacing apart in the first direction, and having an oxide film formed on a surface,
a pair of second conductor patterns extending in the first direction, having a second gap portion for spacing apart in the first direction, and overlapping the pair of first conductor patterns while being shifted in the first direction in such a way as to straddle the first gap portion, and
a Josephson junction portion located between the first gap portion and the second gap portion in plan view and formed by overlapping one of the pair of first conductor patterns and one of the pair of second conductor patterns by way of the oxide film;
a boundary line between the substrate and the pair of main patterns in plan view includes:
an opposing boundary line located on a side where the pair of main patterns face each other in the first direction, and
a non-opposing boundary line other than the opposing boundary line,
the pair of first conductor patterns includes a ride-on portion riding on the pair of main patterns from the substrate; and
the ride-on portion is formed in such a way as to overlap at least the non-opposing boundary line.

10. A method for manufacturing a superconducting quantum circuit comprising:
forming a laminated body of a superconducting material on a substrate, wherein
the step of forming the laminated body includes:
forming a pair of main patterns spaced apart from each other in a first direction on the substrate, and
forming a connection pattern on the substrate and the pair of main patterns to connect the pair of main patterns;
the step of forming the connection pattern includes:
forming a pair of first conductor patterns extending in the first direction and having a first gap portion for spacing apart in the first direction by a first oblique deposition from one side in the first direction Via a mask having a pair of openings spaced apart from each other in the first direction,
forming an oxide film on a surface of the pair of first conductor patterns, and
forming a pair of second conductor patterns extending in the first direction and having a second gap portion for spacing apart in the first direction by a second oblique deposition from the other side in the first direction Via the mask to overlap the pair of first conductor patterns while being shifted in the first direction in such a way as to straddle the first gap portion, and forming a Josephson junction portion located between the first gap portion and the second gap portion in plan View by overlapping one of the pair of first conductor patterns and one of the pair of second conductor patterns by way of the oxide film;
a boundary line between the substrate and the pair of main patterns in plan View includes:
an opposing boundary line located on a side where the pair of main patterns face each other in the first direction, and
a non-opposing boundary line other than the opposing boundary line; and
in the step of forming the pair of first conductor patterns, the pair of first conductor patterns forms a ride-on portion riding on the pair of main patterns from the substrate, and forms the ride-on portion in such a way as to overlap at least the non-opposing boundary line.
